(19) United States
(12) Patent Application Publication
(10) Pub. No.: US 2023/0225074 A1
(43) Pub. Date: Jul. 13, 2023

(54) DATA STORAGE DEVICES WITH AIR MOVERS

(71) Applicant: Seagate Technology LLC, Fremont, CA (US)

(72) Inventors: Antonia Tsoukatos, Maple Grove, MN (US); Akhil Namboori, Singapore (SG)

(21) Appl. No.: 17/574,119

(22) Filed: Jan. 12, 2022

(51) Int. Cl. H05K 7/20; G06F 1/20

(52) U.S. Cl. CPC H05K 7/20145; G06F 1/20; H05K 7/20172

(57) ABSTRACT

An electronic device includes an enclosure, an air mover assembly, and a printed circuit board. The enclosure houses electrical components. The air mover assembly includes at least a portion of a motor, and the printed circuit board is spaced from the enclosure and includes stator coils of the motor within the printed circuit board.

### SUMMARY

In certain embodiments, an electronic device includes an enclosure that houses electrical components, an air mover assembly with at least a portion of a motor, and a printed circuit board spaced from the enclosure and including stator coils of the motor within the printed circuit board.

In certain embodiments, the air mover assembly includes a motor with a stator and a rotor. The stator includes stator coils, and the rotor includes a base that is coupled to a permanent magnet that has blades extending from the base. The air mover assembly further includes a printed circuit board with the stator coils positioned within the printed circuit board.

In certain embodiments, a method includes selectively energizing a set of stator coils to generate magnetic fields, where: the stator coils extend within a common plane, the stator coils are embedded in a printed circuit board, and the generated magnetic fields are directed along a direction perpendicular to the common plane. The method further includes rotating a rotor around the direction perpendicular to the common plane, where: the rotor includes a permanent magnet positioned on a first side of the rotor facing the printed circuit board and the rotor includes blades.

While multiple embodiments are disclosed, still other embodiments of the present invention will become apparent to those skilled in the art from the following detailed description, which shows and describes illustrative embodiments of the invention. Accordingly, the drawings and detailed description are to be regarded as illustrative in nature and not restrictive.

### BRIEF DESCRIPTION OF THE DRAWINGS

FIG. 1 shows an exploded, perspective view of a hard disk drive, in accordance with certain embodiments of the present disclosure.

FIG. 2 shows a side, cut-away view of the hard disk drive of FIG. 1, in accordance with certain embodiments of the present disclosure.

FIG. 3 shows a bottom view of the hard disk drive of FIG. 1 with a printed circuit board assembly attached, in accordance with certain embodiments of the present disclosure.

FIG. 4 shows a bottom view of the hard disk drive of FIG. 1 with a printed circuit board assembly of FIG. 3 detached, in accordance with certain embodiments of the present disclosure.

FIG. 5 shows a side, cut-away schematic of the printed circuit board and an air mover assembly, in accordance with certain embodiments of the present disclosure.

FIGS. 6A and 6B show bottom schematic views of a rotor portion of the air mover assembly, in accordance with certain embodiments of the present disclosure.

FIG. 7 shows a top down schematic view of a stator portion of the air mover assembly, in accordance with certain embodiments of the present disclosure.

FIG. 8 shows a perspective view of another example printed circuit board and an air mover assembly, in accordance with certain embodiments of the present disclosure.

FIG. 9 shows a perspective view of a rotor of the air mover assembly of FIG. 8, in accordance with certain embodiments of the present disclosure.

FIG. 10 shows a top down view of the rotor of the air mover assembly of FIG. 8, in accordance with certain embodiments of the present disclosure.

FIG. 11 shows a block diagram of steps of a method, in accordance with certain embodiments of the present disclosure.

While the disclosure is amenable to various modifications and alternative forms, specific embodiments have been shown by way of example in the drawings and are described in detail below. The intention, however, is not to limit the disclosure to the particular embodiments described but instead is intended to cover all modifications, equivalents, and alternatives falling within the scope of the appended claims.

### DETAILED DESCRIPTION

Data storage systems are used to store and process vast amounts of data. It can be challenging to keep the systems and their components (e.g., data storage devices) within a desired temperature range because of the amount of heat the systems and their components typically generate during operation. Certain embodiments of the present disclosure are accordingly directed to approaches for cooling data storage devices. In particular, certain embodiments involve incorporating air mover assemblies with data storage devices.

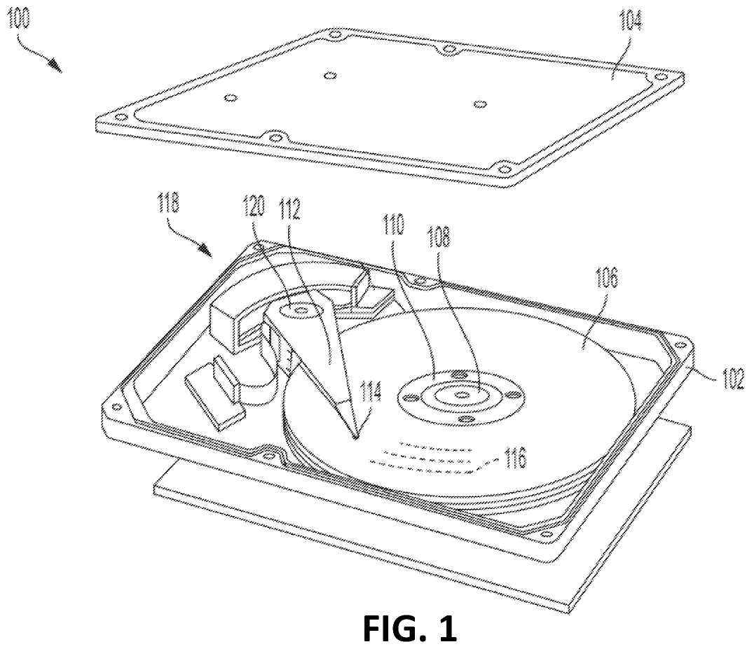

FIG. 1 shows an exploded, perspective view of a data storage device such as a hard disk drive 100. Although a hard disk drive is used as an example throughout the description, the various features for cooling the hard disk drive 100 can be used in connection with other electronic devices and data storage devices.

The hard disk drive 100 includes a base deck 102 (which can also be referred to as a baseplate) and a top cover 104 that, when coupled together, creates an enclosure that houses various components of the hard disk drive 100. The hard disk drive 100 includes magnetic recording media 106 (individually referred to as a magnetic recording medium) coupled to a spindle motor 108 by a disk clamp 110. The hard disk drive 100 also includes an actuator assembly 112 that positions read/write heads 114 over data tracks 116 on the magnetic recording media 106.

During operation, the spindle motor 108 rotates the magnetic recording media 106 while the actuator assembly 112 is driven by a voice coil motor assembly 118 to pivot around a pivot bearing 120. The read/write heads 114 write data to the magnetic recording media 106 by generating and emitting a magnetic field towards the magnetic recording media 106 which induces magnetically polarized transitions on the desired data track 116. The magnetically polarized transitions are representative of the data. The read/write heads 114 sense (or “read”) the magnetically polarized transitions with a magnetic transducer. As the magnetic recording media 106 rotate adjacent the read/write heads 114, the magnetically polarized transitions induce a varying magnetic field into a magnetic transducer of the read/write heads 114. The magnetic transducer converts the varying magnetic field into a read signal that is delivered to a preamplifier and then to a read channel for processing. The read channel converts the read signal into a digital signal that is processed and then provided to a host system (e.g., server, laptop computer, desktop computer).

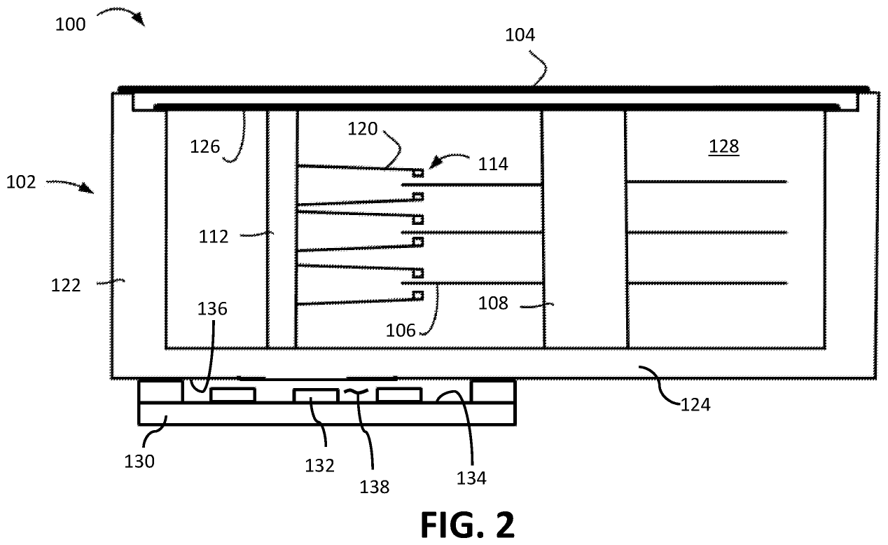

FIG. 2 shows a cut away schematic of the hard disk drive 100. The base deck 102 includes side walls (e.g., side wall 122) that, together with a bottom portion 124 of the base deck 102 and a process cover 126, creates an internal cavity 128 of an enclosure that houses various data storage components. During assembly, the process cover 126 can be coupled to the base deck 102 by removable fasteners (not shown) and a gasket (not shown) to seal a target gas (e.g., air with nitrogen and oxygen and/or a lower-density gas like helium) within the internal cavity 128. Once the process cover 126 is coupled to the base deck 102, a target gas may be injected into the internal cavity 128 through an aperture in the process cover 126, which is subsequently sealed. Injecting the target gas, such as a combination of air and a low-density gas like helium (e.g., 90 percent or greater helium), may involve first evacuating existing gas from the internal cavity 128 using a vacuum and then injecting the target gas from a low-density gas supply reservoir into the internal cavity 128. Once the process cover 126 is sealed, the hard disk drive 100 can be subjected to a variety of processes and tests. After the hard disk drive 100 is processed and passes certain tests, the top cover 104 can be coupled (e.g., welded) to the base deck 102.

FIG. 2 shows the hard disk drive 100 including a printed circuit board 130 coupled to the base deck 102 (e.g., to the bottom portion 124 of the base deck 102). The printed circuit board 130 can be coupled via fasteners that extend through openings in the board and into the base deck 102.

The printed circuit board 130 includes one or more integrated circuits 132. As shown in FIG. 2, the integrated circuits 132 are positioned on a top surface 134 of the printed circuit board 130 that faces a bottom surface 136 of the base deck 102. The integrated circuits 132 extend within a space 138 between the base deck 102 and the printed circuit board 130. In certain embodiments, the distance between the top surface 134 of the printed circuit board 130 and the bottom surface 136 of the base deck 102 is 2-3 millimeters.

During factory testing and in-the-field operation of the hard disk drive 100, the integrated circuits 132 are powered on to carry out various operations of the hard disk drive 100. For example, the integrated circuits 132 can include a system-on-a-chip (SOC) that includes firmware and various microprocessors that manage operations of the hard disk drive 100. These integrated circuits 132 generate heat when operating.

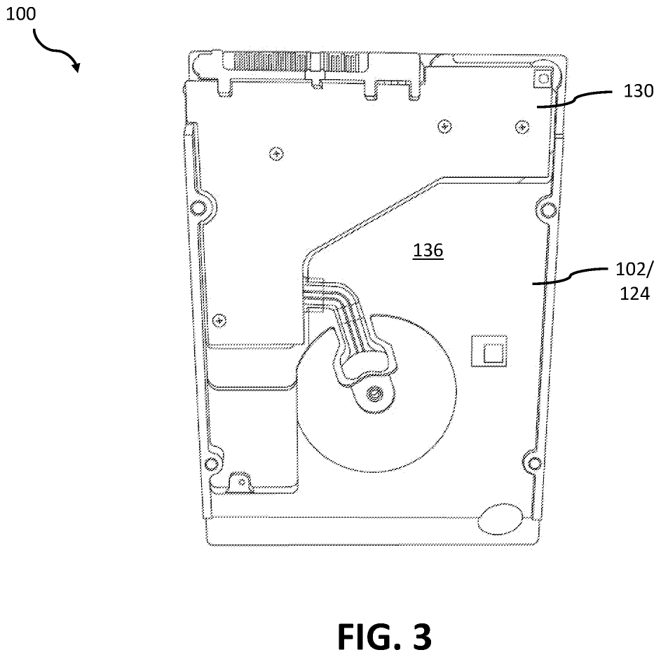

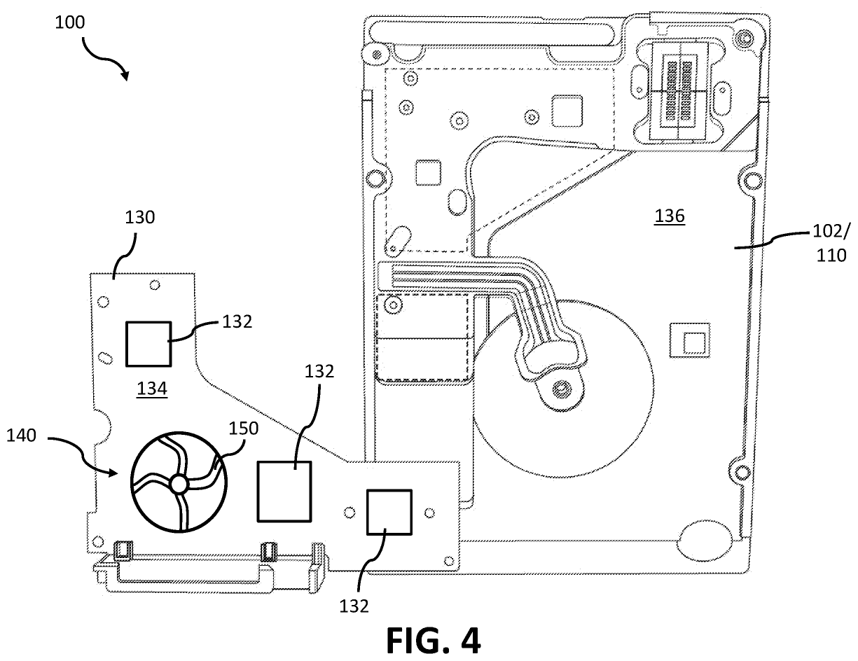

FIG. 3 shows a bottom view of the hard disk drive 100 with the printed circuit board 130 attached to the base deck 102. FIG. 4 shows a bottom view of the hard disk drive 100 with the printed circuit board 130 detached to show example positions of the integrated circuits 132 coupled to the printed circuit board 130. When the hard disk drive 100 is operating, these integrated circuits 132 generate heat in the space (e.g., the space 138 shown in FIG. 2) between the printed circuit board 130 and the base deck 102. The generated heat can create areas of concentrated heat (e.g., local hot spots), which can negatively affect performance of the integrated circuits 132 and the hard disk drive 100. It can be challenging to cool this space and mitigate the risk of hot spots.

To help cool the space (e.g., the space 138 shown in FIG. 2), the hard disk drive 100 can include an air mover assembly 140, which is shown in FIG. 4. Although only one air mover assembly 140 is shown, the hard disk drive 100 can include multiple air mover assemblies.

The air mover assembly 140 can be positioned within the space between the base deck 102 and the printed circuit board 130 and can be coupled to the printed circuit board 130. As will be described in more detail below, the air mover assembly 140 can include fan blades 150 that are rotated to help increase air flow within the space and reduce the risk or extent of local hot spots. The air mover assembly 140 can be positioned, for example, between integrated circuits 126 to help induce airflow across the integrated circuits 126. In other embodiments, the air mover assembly 140 is positioned at, or adjacent to, known hot spot locations.

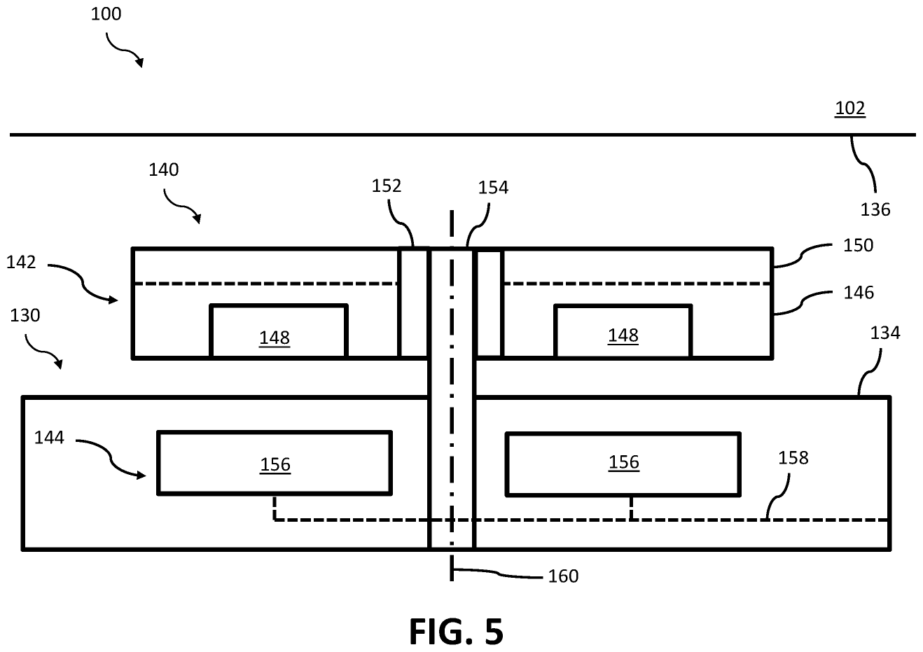

FIG. 5 shows a schematic, cutaway side view of the air mover assembly 140 and a portion of the printed circuit board 130 and base deck 102 of the hard disk drive 100.

The air mover assembly 140 is rotated by a motor, which comprises a rotor portion 142 (hereinafter “the rotor 142” for brevity) and a stator portion 144 (hereinafter “the stator 144” for brevity). Together, the rotor 142 and the stator 144 form the motor.

The rotor 142 is part of the air mover assembly 140 and includes a base portion 146 (hereinafter the “base 146” for brevity). In certain embodiments, the base portion 146 is a toroidal-, disk-, frustoconical-, or plate-shaped structure although other shaped structures could be used. The rotor 142 can also include multiple permanent magnets 148 coupled to the base 146. The rotor 142 can also include fan blades 150 (described in more detail below) that are integrally formed with the base 146 or separately coupled to the base 146.

The base 146 is coupled to a bearing 152, which allows the base 146 to rotate with respect to a shaft 154 (e.g., stationary shaft) that is coupled between the bearing 152 and the printed circuit board 130. The bearing 152 can include grease, lubricant, ball bearings, etc., to permit the base 146 to rotate with a low amount of friction between the stationary and rotating parts of the bearing 152.

The stator 144 includes stator coils 156 (e.g., conductive windings) that are positioned within the printed circuit board 130. For example, the stator coils 156 can be embedded within the printed circuit board 130. By positioning the stator coils 156 within the printed circuit board 130 (as opposed to being positioned external to the printed circuit board 130), the overall height of the motor can be reduced. As a result, the hard disk drive 100 can include the air mover assembly 140 without necessarily needing to increase the space between the printed circuit board 130 and base deck 102 while still being able to fit within standard hard disk drive form factors. The hard disk drive 100 can therefore fit into standard-sized storage slots in server enclosures, desktops, etc.

The printed circuit board 130 can include traces 158 (e.g., conductive traces) that are electrically coupled to the stator coils 156 to provide power to (and therefore energize) the stator coils 156. The traces 158 can be electrically coupled between the stator coils 156 and a power source, such as one of the integrated circuits on the printed circuit board 130 (e.g., the integrated circuits 132 shown in FIGS. 2 and 4).

The stator coils 156 can be created as part of the process of creating the printed circuit board 130. For example, the stator coils 156 can be made of a conductive material like the traces 158. In printed circuit boards, conductive elements can be protected from electric shorts by being covered by an insulating material like a resin, which is sometimes referred to as a solder mask or solder resist. As such, the stator coils 156 and the traces 158 can both be embedded within a cured resin of the printed circuit board 130.

When the stator coils 156 are energized, the stator coils 156 create magnetic fields that interact with the magnetic fields created by the permanent magnets 148 of the rotor 142. The stator coils 156 can be selectively energized to cause the rotor 142 (and therefore the fan blades 150) to rotate around a rotation axis 160. The stator coils 156 can be designed and oriented to generate magnetic fields in an axial direction (e.g., a direction parallel to the rotation axis 160). As such, in certain embodiments, the rotor 142 and the stator 144 can form an axial flux motor. Moreover, the rotor 142 and the stator 144 can form a brushless direct current (BLDC) motor such as a 3-phase BLDC motor.

In certain embodiments, the stator coils 156 are selectively energized such that the rotor 142 rotates at one or more speeds within the range of 500-1,500 revolutions per minute (rpm). At 1,000 rpm, the stator coils 156 may consume a relatively low amount of power such as 80-100 milliwatts. In certain embodiments, the particular rotating speed—or whether any power is provided to the stator coils 156—can depend on factors such as temperature measurements (e.g., from the hard disk drive's temperature sensor) and/or power consumption of other components of the hard disk drive 100. As such, the power consumption of the motor can be modified depending on the current operating environment of the hard disk drive 100.

Although the fan assembly 140 will generate vibration during operation, little vibration is ultimately transferred to the base deck 102 of the hard disk drive 100 because the motor is held by the printed circuit board 130. The mass of the printed circuit board 130 helps isolate and dampen the vibration created by the air mover assembly 140. In certain embodiments, the printed circuit board 130 is a rigid printed circuit rather than a flexible printed circuit.

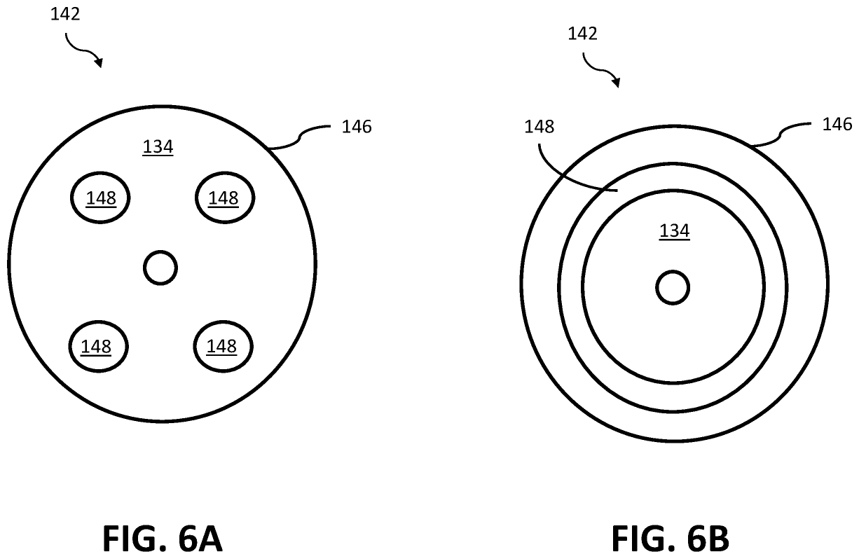

FIGS. 6A and 6B show different arrangements of the rotor 142. The Figures show a bottom surface of the rotor 142 which is the surface facing the top surface of the printed circuit board. In FIG. 6A, the rotor 142 includes four separate permanent magnets 148. These permanent magnets 148 can be attached (e.g., adhered) to the disk 146 of the rotor 142. The permanent magnets 148 can have different polarities and be arranged such that, for example, a negative polarity permanent magnet 148 is positioned between two positive polarity permanent magnets 148. The number of permanent magnets 148 and the number of magnetic poles can vary depending on factors such as the size of the base 146, size of the permanent magnets 148, and desired performance of the motor.

In FIG. 6B, the rotor 142 includes a single permanent magnet 148. The permanent magnet 148 can be attached (e.g., adhered) to the base 146 of the rotor 142. The permanent magnet 148 can be magnetized to have different magnetic poles along the radial direction of the permanent magnet 148 such that the single permanent magnet 148 functions the same as having several separate permanent magnets with different polarities. Using a single permanent magnet can simplify construction of the air mover assembly 140.

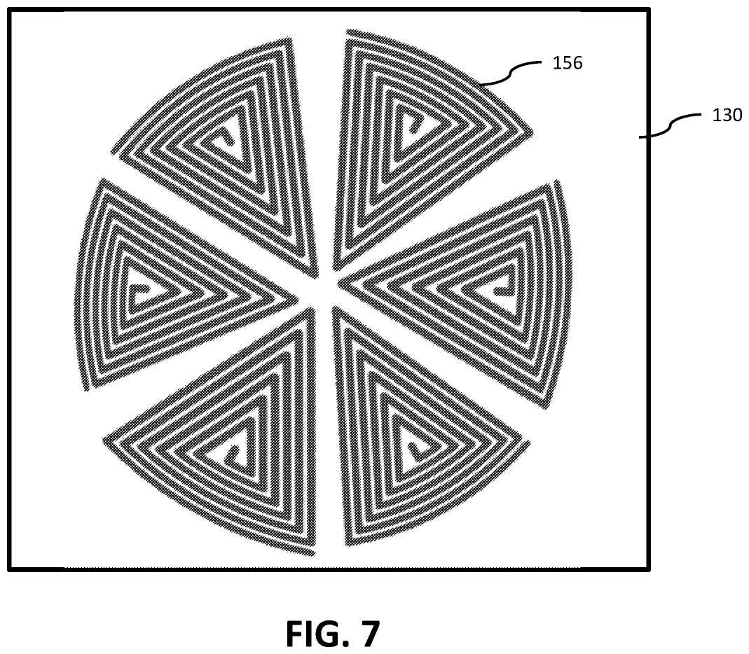

FIG. 7 shows a top view of a portion of the printed circuit board 130 with the stator coils 156 exposed. As previously noted, the printed circuit board 130 houses the stator coils 156. The stator coils 156 can include different sets of windings.

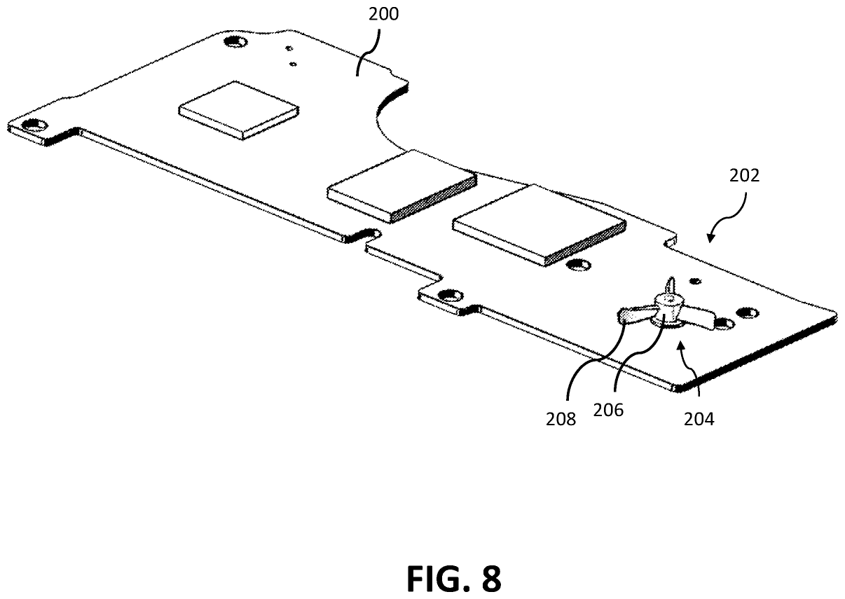

In certain embodiments, like that shown in FIG. 7, the stator coils 156 include six separate sets of coils although the stator coils 156 may include fewer or more sets of coils. Each separate set of coils can include a specified number of windings. In embodiments, the number of windings of each set of coils is 5-8. The shape of the sets of coils can vary but are typically triangular-shaped—although the tips of the triangles can be more rounded than that shown in FIG. 8. The stator coils 156 can be planar such that all the coils are positioned along the same common plane within the printed circuit board 130. This shared common plane can be parallel to the top surface of the printed circuit board 130. In certain embodiments, the stator 144 is considered to be a coreless stator because the stator coils 156 are not wound around a magnetic core.

As noted above, the stator coils 156 can be electrically coupled to traces, which provide power to the stator coils 156. Each of the separate sets of coils can be coupled to a trace of the printed circuit board 130 and wired such that the stator 144 creates a 3-phase motor. When the stator coils 156 are energized, the stator coils 156 create magnetic fields that are directed towards a direction out of the page of FIG. 7 (e.g., perpendicular to the shared common plane the stator coils 156 are positioned within or perpendicular to the top surface of the printed circuit board 130). The different sets of coils can be selectively energized over time to create magnetic fields that interact with those of the permanent magnets to cause the rotor 142 to rotate.

FIG. 8 shows another example of a printed circuit board 200 with an air mover assembly 202. The printed circuit board 200 can be coupled to an electronic device such as the hard disk drive 100 described above.

The air mover assembly 202 includes a rotor 204 with a cylinder-shaped base portion 206. The air mover assembly 202 also includes blades 208. In certain embodiments, the base 206 and the blades 208 are a unitary structure. For example, the base 206 and the blades 208 can be formed by a single mold.

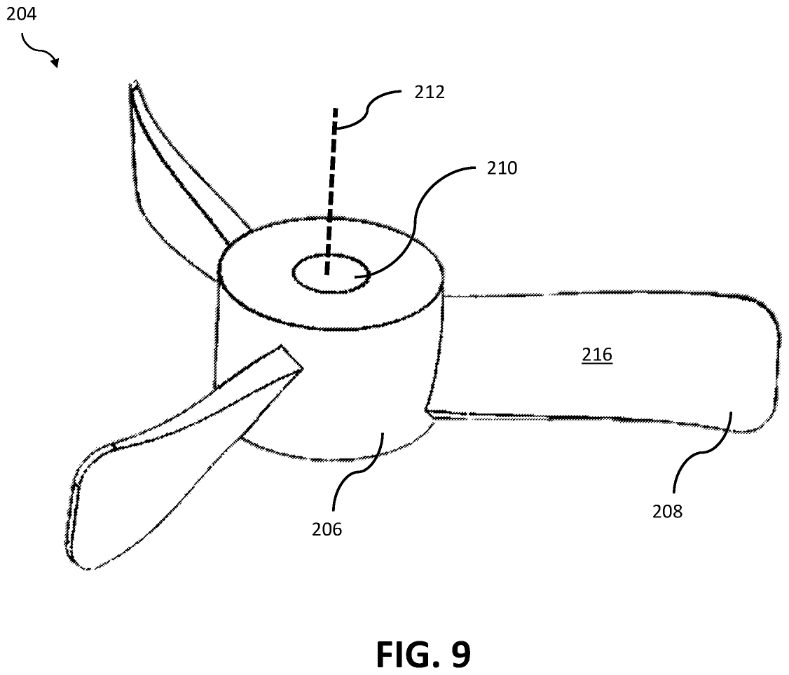

FIG. 9 shows a closer-up view of the rotor 204. As shown, the base 206 includes a central opening 210, which can be sized to allow a shaft to extend through. The blades 208 extend from the base 206 perpendicular to a rotation axis 212 around which the rotor 204 rotates. In the embodiment shown in FIG. 9, the rotor 204 includes three blades 208, however, the rotor 204 could include additional blades.

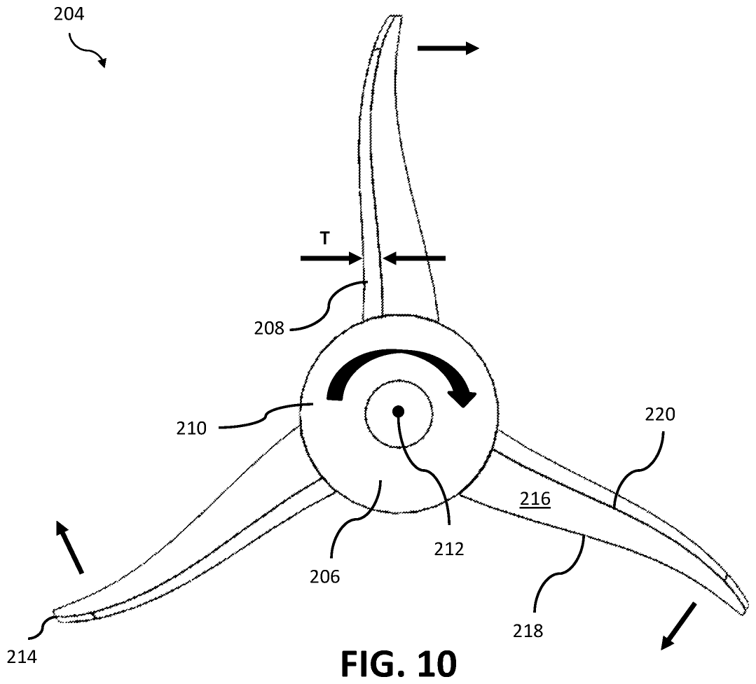

FIG. 10 shows a top view of the rotor 204. As can be seen in FIG. 10, as the blades 208 extend from the base 206 to a distal end 214, a thickness (T) of the blades 208 decreases such that the thickness is the greatest at the base 206 and smallest at the distal end 214. In certain embodiments, the blades 208 have identical geometry and are positioned 120 degrees from each other along the base 206.

Each blade 208 has a leading surface 216 that pushes air as the rotor 204 rotates around the rotation axis 212. The leading surface 216 can be curved such that a bottom leading edge 218 of the blades 208 is offset from a top leading edge 220 of the blades 208. As such, the leading surface 216 is slanted so that air is pushed away from the printed circuit board as the rotor 204 rotates.

Using the air mover assemblies described above, the rotating blades of the air mover assemblies cause air to move within the space between the printed circuit board and the base deck. As the air moves across and around the integrated circuits, heat generated by the integrated circuits can be circulated to other locations within the space or outside the space entirely to help reduce the risk of local hot spots.

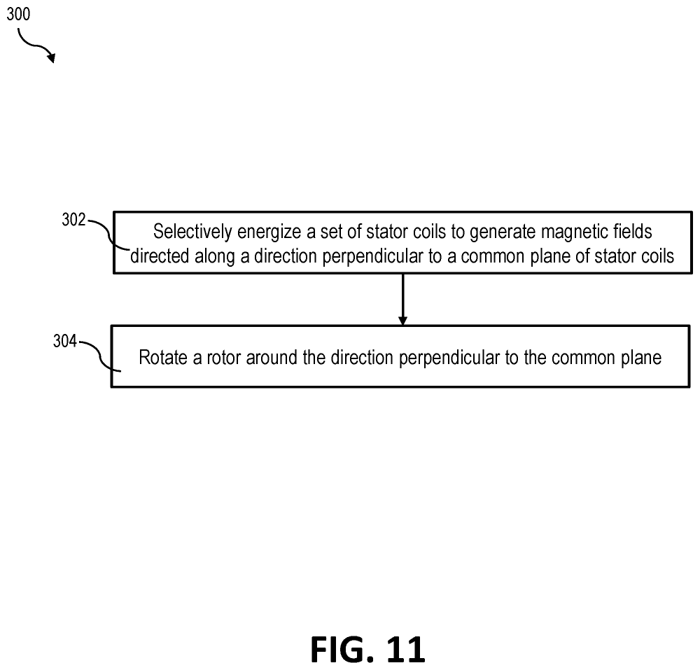

FIG. 11 shows a block diagram of a method 300. The method 300 includes selectively energizing a set of stator coils to generate magnetic fields directed along a direction perpendicular to a common plane of the stator coils (block 302 in FIG. 11). The method 300 further includes rotating a rotor around the direction perpendicular to the common plane (block 304 in FIG. 11). The method 300 may also include the various steps or processes described above and utilize the various devices, assemblies, and components described above.

Various modifications and additions can be made to the embodiments disclosed without departing from the scope of this disclosure. For example, while the embodiments described above refer to particular features, the scope of this disclosure also includes embodiments having different combinations of features and embodiments that do not include all of the described features. Accordingly, the scope of the present disclosure is intended to include all such alternatives, modifications, and variations as falling within the scope of the claims, together with all equivalents thereof.

We claim:

1. An electronic device comprising:
an enclosure housing electrical components;
an air mover assembly comprising at least a portion of a motor; and
a printed circuit board spaced from the enclosure and including stator coils of the motor within the printed circuit board.

2. The electronic device of claim 1, wherein the portion of the motor includes a rotor portion.

3. The electronic device of claim 2, wherein the rotor portion includes multiple permanent magnets.

4. The electronic device of claim 2, wherein the rotor portion includes a single permanent magnet.

5. The electronic device of claim 1, wherein the air mover assembly further comprises fan blades.

6. The electronic device of claim 5, wherein the fan blades are part of a rotor portion, wherein the rotor portion further includes a permanent magnet.

7. The electronic device of claim 6, wherein the fan blades extend from a cylinder-shaped base structure.

8. The electronic device of claim 5, wherein a thickness of the fan blades decreases as the fan blades extend to their respective distal ends.

9. The electronic device of claim 1, wherein the motor is an axial flux motor.

10. The electronic device of claim 1, wherein the motor is a brushless direct current motor.

11. The electronic device of claim 1, wherein the motor includes a coreless stator.

12. The electronic device of claim 1, wherein the electrical components are data storage components.

13. The electronic device of claim 1, wherein the printed circuit board is a rigid printed circuit board.

14. The electronic device of claim 1, wherein the stator coils are embedded in a cured resin.

15. The electronic device of claim 1, wherein the electronic device is a hard disk drive, wherein the enclosure comprises a base deck, wherein the air mover assembly is configured to move air within a space between the base deck and the printed circuit board.

16. The electronic device of claim 15, wherein the air mover assembly is positioned between integrated circuits coupled to the printed circuit board.

17. An air mover assembly comprising:
a motor with a stator and a rotor, the stator including stator coils, the rotor including a base that is coupled to a permanent magnet and that includes blades extending from the base; and
a printed circuit board including the stator coils positioned within the printed circuit board.

18. The air mover assembly of claim 18, further comprising a bearing and a stationary shaft, wherein the bearing is coupled between the base and the stationary shaft, wherein the stationary shaft is coupled between the bearing and the printed circuit board.

19. The air mover assembly of claim 18, wherein the motor is an axial flux motor.

20. A method comprising:
selectively energizing a set of stator coils to generate magnetic fields, wherein the stator coils extend within a common plane, wherein the stator coils are embedded in a printed circuit board, wherein the generated magnetic fields are directed along a direction perpendicular to the common plane; and
rotating a rotor around the direction perpendicular to the common plane, wherein the rotor includes a permanent magnet positioned on a first side of the rotor facing the printed circuit board, wherein the rotor includes blades.
